(19) United States
(12) Patent Application Publication
(10) Pub. No.: US 2018/0212129 A1
(43) Pub. Date: Jul. 26, 2018

(54) HEAT DISSIPATION CIRCUIT BOARD AND METHOD FOR PRODUCING HEAT DISSIPATION CIRCUIT BOARD

(71) Applicants: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(72) Inventors: Hirohisa SAITO, Osaka (JP); Kensaku MOTOKI, Shiga (JP)

(73) Assignees: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(21) Appl. No.: 15/329,025

(22) PCT Filed: Jul. 29, 2015
(86) PCT No.: PCT/JP2015/071465

§ 371 Date: Jan. 25, 2017

(30) Foreign Application Priority Data
Jul. 30, 2014 (JP) 2014-155063

(51) Int. Cl. H01L 33/64; H01L 25/075; H01L 33/62; H01L 23/538

(52) U.S. Cl. CPC H01L 33/647; H01L 25/0753; H01L 33/62; H01L 2933/0075; H01L 23/5387; H01L 2933/0066; H01L 33/641

(57) ABSTRACT

A heat dissipation circuit board includes a printed circuit board including an insulating film and a conductive pattern that is formed on a front-surface side of the insulating film and includes at least one land part and a wiring part connected to the at least one land part; and at least one electronic component mounted on a front-surface side of the at least one land part. In the heat dissipation circuit board, the printed circuit board includes a recess on a side opposite to a side on which the at least one electronic component is mounted, the recess being in at least a portion of a projection region of the at least one land part, the recess extending to the conductive pattern, and includes a thermally conductive adhesive layer filling the recess. Furthermore, in the heat dissipation circuit board, the insulating film remains, in plan view, in a region including, in the at least one land part, at least a portion of a connecting boundary to the wiring part or at least a portion of a peripheral edge facing the connecting boundary.

### TECHNICAL FIELD

The present invention relates to a heat dissipation circuit board and a method for producing a heat dissipation circuit board.

### BACKGROUND ART

Some electronic components mounted on printed circuit boards, such as light-emitting diodes (LEDs), generate a large amount of heat during operation. In general, printed circuit boards on which electronic components generating a large amount of heat are mounted include, for example, heat dissipation metal plates thereon in order to prevent degradation of the performance of electronic components and damage to circuits due to heat.

In order to further enhance the heat dissipation effect for electronic components, for example, the following articles were devised: a circuit board in which a metal plate is bonded to a printed circuit board with a thermally conductive adhesive having a high thermal conductivity (Patent Literature 1); and a circuit board in which a conductive pattern is directly formed on a metal plate with a thermally conductive adhesive therebetween (Patent Literature 2).

### CITATION LIST

### Patent Literature

PTL 1: Japanese Unexamined Patent Application Publication No. 6-232514

PTL 2: Japanese Unexamined Patent Application Publication No. 9-139580

### SUMMARY OF INVENTION

### Technical Problem

The above-described circuit board in which a metal plate is bonded to a printed circuit board with a thermally conductive adhesive has an insulating film between the metal plate and an electronic component (conductive pattern), so that a sufficient heat dissipation effect is less likely to be provided. For this reason, in the case of using the circuit board for an LED lighting apparatus with plural LEDs that is becoming widespread in these years, limitations are placed on usage conditions, which is disadvantageous.

In the above-described circuit board in which a conductive pattern is formed on a metal plate with a thermally conductive adhesive therebetween, for example, curving of the substrate may cause, for example, breakage of the cured thermally conductive adhesive and the insulation property is degraded, which is disadvantageous.

The present invention has been made under the above-described circumstances. An object is to provide a heat dissipation circuit board that has high insulation reliability and can effectively promote heat dissipation from an electronic component, and a method for producing the heat dissipation circuit board.

### Solution to Problem

A heat dissipation circuit board according to an embodiment of the present invention having been made to achieve the above-described object includes a printed circuit board including an insulating film and a conductive pattern that is formed on a front-surface side of the insulating film and includes at least one land part and a wiring part connected to the at least one land part; and at least one electronic component mounted on a front-surface side of the at least one land part. In the heat dissipation circuit board, the printed circuit board includes a recess on a side opposite to a side on which the at least one electronic component is mounted, the recess being in at least a portion of a projection region of the at least one land part, the recess extending to the conductive pattern, and includes a thermally conductive adhesive layer filling the recess. Furthermore, in the heat dissipation circuit board, the insulating film remains, in plan view, in a region including, in the at least one land part, at least a portion of a connecting boundary to the wiring part or at least a portion of a peripheral edge facing the connecting boundary.

A method for producing a heat dissipation circuit board according to another embodiment of the present invention having been made to achieve the above-described object is a method for producing a heat dissipation circuit board including a printed circuit board including an insulating film and a conductive pattern that is formed on a front-surface side of the insulating film and includes at least one land part and a wiring part connected to the at least one land part, and at least one electronic component mounted on a front-surface side of the at least one land part. The production method includes a step of mounting the at least one electronic component on the at least one land part; a step of forming a recess on a side of the printed circuit board, the side being opposite to a side on which the at least one electronic component is mounted, the recess being in at least a portion of a projection region of the at least one land part, the recess extending to the conductive pattern; and a step of filling the recess with a thermally conductive adhesive. In the method for producing a heat dissipation circuit board, in the step of forming the recess, the insulating film is removed except for, in plan view, a region including, in the at least one land part, at least a portion of a connecting boundary to the wiring part or at least a portion of a peripheral edge facing the connecting boundary.

### Advantageous Effects of Invention

A heat dissipation circuit board according to an embodiment of the present invention and a heat dissipation circuit board produced by a method for producing a heat dissipation circuit board according to another embodiment of the present invention have high insulation reliability and can effectively promote heat dissipation from mounted electronic components. Thus, circuit boards suitably used for, for example, LED lighting apparatuses can be provided.

### BRIEF DESCRIPTION OF DRAWINGS

FIG. 1A is a schematic sectional view of a heat dissipation circuit board according to a first embodiment of the present invention.

FIG. 1B is a schematic partial plan view of the flexible printed circuit board in FIG. 1A, viewed from the front-surface side.

FIG. 2 is a schematic sectional view illustrating a step of a method for producing the heat dissipation circuit board in FIG. 1A.

FIG. 3 is a schematic sectional view illustrating a step, subsequent to the step in FIG. 2, of the method for producing the heat dissipation circuit board in FIG. 1A.

FIG. 4 is a schematic sectional view illustrating a step, subsequent to the step in FIG. 3, of the method for producing the heat dissipation circuit board in FIG. 1A.

FIG. 5 is a schematic sectional view illustrating a step, subsequent to the step in FIG. 4, of the method for producing the heat dissipation circuit board in FIG. 1A.

FIG. 6 is a schematic sectional view illustrating a step, subsequent to the step in FIG. 5, of the method for producing the heat dissipation circuit board in FIG. 1A.

FIG. 7 is a schematic sectional view of a heat dissipation circuit board according to an embodiment other than the embodiment in FIG. 1A.

FIG. 8 is a schematic sectional view of a heat dissipation circuit board according to an embodiment other than the embodiments in FIG. 1A and FIG. 7.

FIG. 9 is a schematic sectional view of a heat dissipation circuit board according to an embodiment other than the embodiments in FIG. 1A, FIG. 7, and FIG. 8.

FIG. 10 is a schematic plan view of a heat dissipation circuit board according to an embodiment other than the embodiments in FIG. 1A, FIG. 7, FIG. 8, and FIG. 9.

### DESCRIPTION OF EMBODIMENTS

### Description of Embodiments of the Present Invention

A heat dissipation circuit board according to an embodiment of the present invention includes a printed circuit board including an insulating film and a conductive pattern that is formed on a front-surface side of the insulating film and includes at least one land part and a wiring part connected to the at least one land part; and at least one electronic component mounted on a front-surface side of the at least one land part. In the heat dissipation circuit board, the printed circuit board includes a recess on a side opposite to a side on which the at least one electronic component is mounted, the recess being in at least a portion of a projection region of the at least one land part, the recess extending to the conductive pattern, and includes a thermally conductive adhesive layer filling the recess. Furthermore, in the heat dissipation circuit board, the insulating film remains, in plan view, in a region including, in the at least one land part, at least a portion of a connecting boundary to the wiring part or at least a portion of a peripheral edge facing the connecting boundary.

The heat dissipation circuit board includes a recess in at least a portion of the projection region of such a land part for an electronic component, the recess extending to the conductive pattern; and the recess is filled with a thermally conductive adhesive. Thus, the thermally conductive adhesive layer is directly formed on the conductive pattern of the printed circuit board. As a result, when the heat dissipation circuit board is placed onto a thermally conductive base member such as a metal plate, the conductive pattern and the thermally conductive base member are connected together via the thermally conductive adhesive. This can considerably promote the heat dissipation effect for the electronic component. In the heat dissipation circuit board, the insulating film remains in a region including, in the land part, at least a portion of the connecting boundary to the wiring part or at least a portion of the peripheral edge facing the connecting boundary. As a result, when a printed circuit board with an electronic component mounted thereon is bonded to a thermally conductive base member, occurrence of short circuits caused by contacting of the conductive pattern with the thermally conductive base member can be prevented.

Incidentally, the terms “front surface” and “back surface” are defined as follows: one of the sides of the insulating film on which the conductive pattern is formed is denoted by “front surface”, and the other side is denoted by back surface. These terms do not limit the positional relationship during usage. The phrase “the projection region of a land part” means a portion or the whole of the projection region of the land part. Specifically, for example, depending on the shape or properties of the electronic component mounted, the projection region of the land part may have a region in which heat dissipation is less likely to be ensured (region in which the heat dissipation effect is not promoted even in the case of bonding via a thermally conductive adhesive to the thermally conductive base member). In such a region in which heat dissipation is less likely to be ensured, the recess is not necessarily formed; however, the recess can be formed in the other region of the projection region of the land part and the recess can be filled with a thermally conductive adhesive. Thus, advantages of the present invention can be provided. In other words, the present invention also encompasses an embodiment in which a portion of the projection region of the land part is not included in the recess. The phrase “connecting boundary to the wiring part” means the boundary between the wiring part and the land part. The phrase “peripheral edge facing the connecting boundary to the wiring part” means a portion of the peripheral edges of the land part, the portion intersecting imaginary straight lines that pass points on the connecting boundary and the geometric center of gravity of the land part.

The insulating film is preferably present, in plan view, in a region including, in the at least one land part, the peripheral edge facing the connecting boundary to the wiring part. In this configuration where the insulating film is present, in such a land part, in the peripheral edge facing the connecting boundary to the wiring part; during placement of the printed circuit board onto, for example, a thermally conductive base member, the conductive pattern can be prevented from contacting the thermally conductive base member with more certainty.

A mean overlapped width between a projection region of a remaining portion of the insulating film and a projection region of the at least one land part is preferably 10 μm or more and 500 μm or less. This configuration where the remaining portion of the insulating film has a mean overlapped width in such a range enables enhancement of heat dissipation and also enables further enhancement of the effect of preventing contacts between the conductive pattern and the thermally conductive base member. Incidentally, the term “mean overlapped width” means a value obtained by dividing the overlapped area between the projection region of such a land part and the projection region of the remaining portion of the insulating film, by the length of a portion of the peripheral edges of the projection region of the land part, the portion overlapping the projection region of the remaining portion of the insulating film.

The insulating film may be present, in plan view, in a region including, in the at least one land part, the connecting boundary to the wiring part. In this configuration where the insulating film is present, in such a land part, in the connecting boundary to the wiring part; during placement of the printed circuit board onto, for example, a thermally conductive base member, the conductive pattern can also be prevented from contacting the thermally conductive base member.

The thermally conductive adhesive layer includes a first thermally conductive adhesive layer formed on the conductive pattern, and a second thermally conductive adhesive layer formed on the first thermally conductive adhesive layer. The second thermally conductive adhesive layer may have a thermal conductivity equal to or lower than a thermal conductivity of the first thermally conductive adhesive layer. In this way, when the thermally conductive adhesive layer is formed so as to be constituted by two different layers, the first layer (first thermally conductive adhesive layer) formed can be examined for the presence or absence of voids before the second layer (second thermally conductive adhesive layer) is formed. Thus, filling with the adhesive can be achieved with more certainty to prevent degradation of the thermal conduction property and adhesion strength. In addition, the second thermally conductive adhesive layer is formed so as to have a thermal conductivity equal to or lower than the thermal conductivity of the first thermally conductive adhesive layer. In other words, the first thermally conductive adhesive layer is formed so as to have a thermally conductive filler content equal to or higher than the thermally conductive filler content of the second thermally conductive adhesive layer, to thereby maintain the heat dissipation effect of the entirety of the thermally conductive adhesive layer and also to enhance the adhesion strength to, for example, a thermally conductive base member.

The recess preferably has a diameter increased stepwise so as to have a larger opening on a back side and a smaller opening on a front side. In this configuration where the recess has an opening diameter increased stepwise, the recess is easily filled with a thermally conductive adhesive.

The printed circuit board is preferably a flexible printed circuit board having flexibility. When the printed circuit board has flexibility, it can be easily placed onto, for example, a thermally conductive base member having, for example, a curved surface.

A thermally conductive base member on a surface of the thermally conductive adhesive layer is preferably further included, the surface (back surface) being on a side opposite to the conductive pattern. In this configuration where the thermally conductive base member is connected to the conductive pattern via the thermally conductive adhesive alone, the above-described heat dissipation effect is provided with ease and certainty.

The thermally conductive base member is preferably formed of aluminum or an aluminum alloy. This use of aluminum or an aluminum alloy can enhance the thermal conduction property, workability, and a reduction in the weight of the thermally conductive base member.

The thermally conductive base member preferably contains alumite in a surface that is disposed on the thermally conductive adhesive layer. In this configuration where the thermally conductive base member contains alumite in a surface that is disposed on the thermally conductive adhesive layer, durability can be enhanced, which leads to enhancement of dielectric strength.

A method for producing a heat dissipation circuit board according to another embodiment of the present invention is a method for producing a heat dissipation circuit board including a printed circuit board including an insulating film and a conductive pattern that is formed on a front-surface side of the insulating film and includes at least one land part and a wiring part connected to the at least one land part, and at least one electronic component mounted on a front-surface side of the at least one land part. The production method includes a step of mounting the at least one electronic component on the at least one land part; a step of forming a recess on a side of the printed circuit board, the side being opposite to a side on which the at least one electronic component is mounted, the recess being in at least a portion of a projection region of the at least one land part, the recess extending to the conductive pattern; and a step of filling the recess with a thermally conductive adhesive. In the production method, in the step of forming the recess, the insulating film is removed except for, in plan view, a region including, in the at least one land part, at least a portion of a connecting boundary to the wiring part or at least a portion of a peripheral edge facing the connecting boundary.

In the method for producing a heat dissipation circuit board, the recess is formed on a side of the printed circuit board, the side being opposite to a side on which such an electronic component is mounted, the recess being in at least a portion of the projection region of such a land part, the recess extending to the conductive pattern; and this recess is filled with a thermally conductive adhesive. Thus, a heat dissipation circuit board can be produced that has a thermally conductive adhesive layer in contact with the back surface of the land part of the conductive pattern. In other words, the method for producing a heat dissipation circuit board provides a heat dissipation circuit board in which the heat dissipation effect for the electronic component is considerably promoted when the heat dissipation circuit board is placed onto a heat dissipation member such as a thermally conductive base member. In addition, the method for producing a heat dissipation circuit board is performed such that the insulating film is left in a region including, in the land part, at least a portion of the connecting boundary to the wiring part or at least a portion of the peripheral edge facing the connecting boundary. As a result, a heat dissipation circuit board can be produced in which, during placement of the printed circuit board onto, for example, a thermally conductive base member, occurrence of short circuits caused by contacting of the conductive pattern with the thermally conductive base member can be prevented.

### Details of Embodiments of the Present Invention

Hereinafter, embodiments according to the present invention will be described in detail with reference to drawings.

### First Embodiment

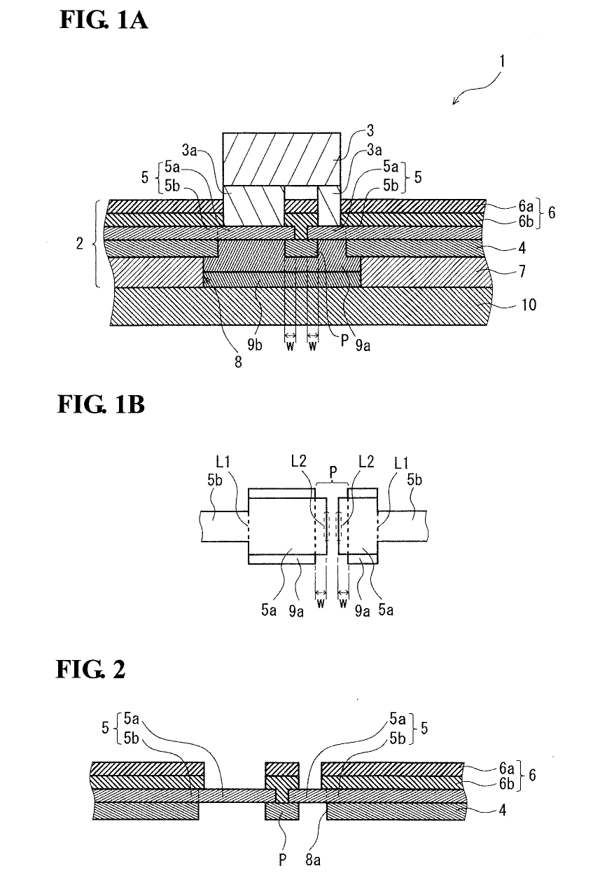

A heat dissipation circuit board 1 illustrated in FIG. 1A mainly includes a flexible printed circuit board 2 having flexibility, a light-emitting diode 3 mounted on this flexible printed circuit board 2, and a thermally conductive base member 10 disposed on the back-surface side of the flexible printed circuit board 2.

### <Flexible Printed Circuit Board>

The flexible printed circuit board 2 includes an insulating film 4; a conductive pattern 5 disposed on the front-surface side of this insulating film 4 and including plural land parts 5a on which the light-emitting diode 3 is mounted and wiring parts 5b connected to the land parts 5a; a coverlay 6 disposed on the front surfaces of the insulating film 4 and the conductive pattern 5; and an adhesive layer 7 disposed on the back surface of the insulating film 4. This flexible printed circuit board 2 includes a recess 8 on a side opposite to a side on which the light-emitting diode 3 is mounted, the recess 8 being in at least a portion of the projection region of the land parts 5a, the recess 8 extending to the conductive pattern 5. This recess 8 is filled with thermally conductive adhesive layers 9a and 9b. Incidentally, the conductive pattern 5 may be disposed on an adhesive applied to the front surface of the insulating film 4.

### (Insulating Film)

The insulating film 4 of the flexible printed circuit board 2 is constituted by a sheet-shaped member having an insulation property and flexibility. The insulating film 4 also has an opening that defines the front-side portion of the recess 8.

Specifically, the sheet-shaped member constituting the insulating film 4 may be a resin film. The main component of this resin film is preferably polyimide, a liquid crystal polymer, a fluororesin, polyethylene terephthalate, or polyethylene naphthalate. Incidentally, the insulating film 4 may contain, for example, a filler or an additive. The term “main component” means a component with a content of 50 mass % or more.

Such liquid crystal polymers include thermotropic polymers, which exhibit liquid crystallinity in a molten state, and lyotropic polymers, which exhibit liquid crystallinity in a solution state. In the present invention, thermotropic liquid crystal polymers are preferably used.

Such a liquid crystal polymer is, for example, an aromatic polyester obtained by synthesis between an aromatic dicarboxylic acid and a monomer such as an aromatic diol or an aromatic hydroxycarboxylic acid. Typical examples of the liquid crystal polymer include a polymer synthesized from p-hydroxybenzoic acid (PHB), terephthalic acid, and 4,4′-biphenol through polymerization of monomers represented by the following formulae (1), (2), and (3); a polymer synthesized from PHB, terephthalic acid, and ethylene glycol through polymerization of monomers represented by the following formulae (3) and (4); and a polymer synthesized from PHB and 2,6-hydroxynaphthoic acid through polymerization of monomers represented by the following formulae (2), (3), and (5).

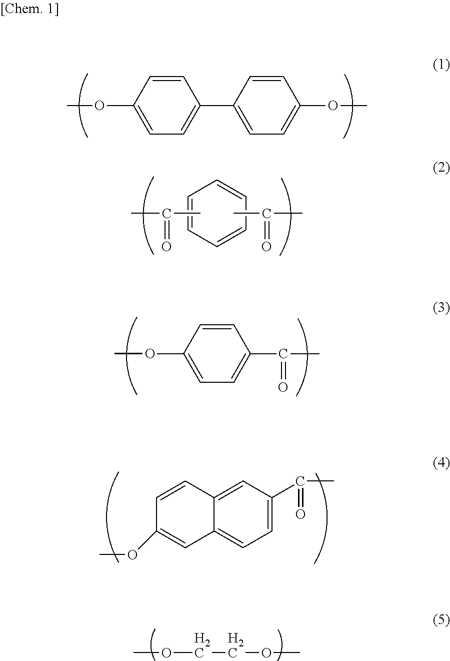

Such a liquid crystal polymer is not particularly limited as long as it exhibits liquid crystallinity. The liquid crystal polymer may contain one of the above-described polymers as the main polymer (in 50 mol % or more in the liquid crystal polymer), and another polymer or monomer being copolymerized. The liquid crystal polymer may be liquid crystal polyester amide, liquid crystal polyester ether, liquid crystal polyester carbonate, or liquid crystal polyester imide.

The liquid crystal polyester amide is a liquid crystal polyester having amide bonds, and an example thereof is a polymer obtained by polymerization of a monomer represented by the following formula (6) and monomers represented by formulae (2) and (4) above.

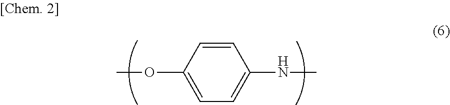

The liquid crystal polymer is preferably produced by subjecting, to melt polymerization, starting monomers corresponding to constitutional units constituting the polymer, and subjecting the resultant polymeric substance (pre-polymer) to solid state polymerization. This enables highly operable production of a high-molecular-weight liquid crystal polymer having, for example, high heat resistance, high strength, and high rigidity. The melt polymerization can be carried out in the presence of a catalyst. Examples of the catalyst include metal compounds such as magnesium acetate, stannous acetate, tetrabutyl titanate, lead acetate, sodium acetate, potassium acetate, and antimony trioxide; and nitrogen-containing heterocyclic compounds such as 4-(dimethylamino)pyridine and 1-methylimidazole. Nitrogen-containing heterocyclic compounds are preferably used.

The above-described fluororesin denotes a resin in which at least one hydrogen atom bonded to a carbon atom constituting a repeating unit of the polymer chain is substituted with a fluorine atom or an organic group containing a fluorine atom (hereafter also referred to as a “fluorine atom-containing group”). The fluorine atom-containing group is a group in which at least one hydrogen atom in a straight or branched organic group is substituted with a fluorine atom. Examples of the fluorine atom-containing group include a fluoroalkyl group, a fluoroalkoxy group, and a fluoropolyether group.

The term “fluoroalkyl group” means an alkyl group in which at least one hydrogen atom is substituted with a fluorine atom, and encompasses the “perfluoroalkyl group”. Specifically, the term “fluoroalkyl group” encompasses, for example, an alkyl group in which all the hydrogen atoms are substituted with fluorine atoms, and an alkyl group in which all the hydrogen atoms except for one end hydrogen atom are substituted with fluorine atoms.

The term “fluoroalkoxy group” means an alkoxy group in which at least one hydrogen atom is substituted with a fluorine atom, and encompasses the “perfluoroalkoxy group”. Specifically, the term “fluoroalkoxy group” encompasses, for example, an alkoxy group in which all the hydrogen atoms are substituted with fluorine atoms, and an alkoxy group in which all the hydrogen atoms except for one end hydrogen atom are substituted with fluorine atoms.

The term “fluoropolyether group” denotes a monovalent group including plural alkylene oxide chains as repeating units, and including an alkyl group or a hydrogen atom at an end. The fluoropolyether group means a monovalent group in which at least one hydrogen atom in the alkylene oxide chain and/or the end alkyl group or hydrogen atom is substituted with a fluorine atom. The term “fluoropolyether group” encompasses the “perfluoropolyether group” including plural perfluoroalkylene oxide chains as repeating units.

The fluororesin is preferably a tetrafluoroethylene-hexafluoropropylene copolymer (FEP), a tetrafluoroethylene-perfluoroalkyl vinyl ether copolymer (PFA), polytetrafluoroethylene (PTFE), polyvinylidene fluoride (PVDF), fluoroelastomer, a tetrafluoroethylene-hexafluoropropylene-vinylidene fluoride copolymer (THV), or a tetrafluoroethylene-perfluorodioxole copolymer (TFE/PDD).

The lower limit of the average thickness of the insulating film 4 is preferably 5 μm, more preferably 12 μm. On the other hand, the upper limit of the average thickness of the insulating film 4 is preferably 50 μm, more preferably 30 μm. When the insulating film 4 has an average thickness less than the lower limit, the insulating film 4 may have an insufficient strength. Conversely, when the insulating film 4 has an average thickness more than the upper limit, the flexible printed circuit board 2 may have insufficient flexibility.

### (Conductive Pattern)

The conductive pattern 5 has a planar configuration (pattern) including plural land parts 5a and wiring parts 5b connected to the land parts 5a. The conductive pattern 5 can be formed of a conductive material, preferably a metal, in general, copper, for example. The conductive pattern 5 is formed by, for example, selectively etching a metal layer formed on the front surface of the insulating film 4.

In the heat dissipation circuit board 1, for the single light-emitting diode 3, the land parts 5a forming a pair are disposed such that their connecting boundaries to the wiring parts 5b face each other. In other words, the land parts 5a forming a pair are disposed so as to be connected, in reverse directions, to the wiring parts 5b.

The lower limit of the average thickness of the conductive pattern 5 is preferably 5 μm, more preferably 8 μm. On the other hand, the upper limit of the average thickness of the conductive pattern 5 is preferably 50 μm, more preferably 40 μm. When the conductive pattern 5 has an average thickness less than the lower limit, electric conduction may become insufficient. Conversely, when the conductive pattern 5 has an average thickness more than the upper limit, the flexible printed circuit board 2 may have insufficient flexibility.

### (Coverlay)

The coverlay 6 is disposed on a portion of the front surface of the flexible printed circuit board 2, the portion excluding a portion where the light-emitting diode 3 is mounted (on the front-surface side of the land parts 5a). This coverlay 6, which has an insulating function and a bonding function, is bonded to the front surfaces of the insulating film 4 and the conductive pattern 5. As illustrated in FIG. 1A, when the coverlay 6 includes an insulating layer 6a and an adhesion layer 6b, the insulating layer 6a may be formed of the same material as that of the insulating film 4, and may have the same average thickness as that of the insulating film 4. An adhesive forming the adhesion layer 6b of the coverlay 6 is preferably, for example, an epoxy-based adhesive. The insulating layer 6a preferably has an average thickness of, for example, 5 μm or more and 50 μm or less. The adhesion layer 6b preferably has an average thickness of, for example, 12.5 μm or more and 60 μm or less.

The front surface of the coverlay 6 is preferably colored so as to be white. A white layer is formed on the front surface of the coverlay 6, so that light emitted from the light-emitting diode 3 to the flexible printed circuit board 2 is reflected, to thereby enhance the usage efficiency of light. In addition, the heat dissipation circuit board 1 can be made more aesthetic. This white layer can be formed by, for example, applying a coating solution containing a white pigment and a binder for the pigment.

### (Adhesive Layer)

The thermally conductive base member 10 is disposed on the back-surface side of the insulating film 4 with the adhesive layer 7 therebetween. The adhesive layer 7 surrounds the thermally conductive adhesive layers 9a and 9b described below, to thereby provide the function of preventing leakage of the thermally conductive adhesive layers 9a and 9b. The adhesive layer 7 contains, as the main component, an adhesive with which the flexible printed circuit board 2 can be bonded to the thermally conductive base member 10. The adhesive is not particularly limited, and examples thereof include thermosetting adhesives such as epoxy-based adhesives, silicone-based adhesives, and acrylic-based adhesives. The adhesive layer 7 may optionally contain an additive. However, since the heat dissipation circuit board 1 includes the thermally conductive adhesive layers 9a and 9b, a thermal conduction property is not necessarily imparted to the adhesive layer 7.

The lower limit of the average thickness of the adhesive layer 7 is preferably 5 μm, more preferably 10 μm. On the other hand, the upper limit of the average thickness of the adhesive layer 7 is preferably 50 μm, more preferably 25 μm. When the adhesive layer 7 has an average thickness less than the lower limit, the bonding strength between the insulating film 4 and the thermally conductive base member 10 may become insufficient. Conversely, when the adhesive layer 7 has an average thickness more than the upper limit, the heat dissipation circuit board 1 may have an excessively large thickness, or the distance between the conductive pattern 5 and the thermally conductive base member 10 may become large, which may result in insufficient heat dissipation.

The adhesive layer 7 has an opening that defines the back-side portion of the recess 8, which is filled with the thermally conductive adhesive layers 9a and 9b. This back-side portion, that is, an opening of the recess 8 in the adhesive layer 7 has a larger size than the front-side portion of the recess 8, that is, an opening of the recess 8 in the insulating film 4. The opening of the recess 8 in the adhesive layer 7 is thus formed so as to have a larger size, to thereby facilitate the process of filling with the thermally conductive adhesive layers 9a and 9b. In addition, when the insulating film 4 is removed to form the front-side portion of the recess 8, and the adhesive layer 7 having an opening defining the back-side portion of the recess 8 is subsequently placed on the front-side portion, alignment between these portions is facilitated.

### (Recess)

The heat dissipation circuit board 1 includes the recess 8 on a side of the flexible printed circuit board 2, the side being opposite to a side on which the light-emitting diode 3 is mounted, the recess 8 being in at least a portion of the projection region of the land parts 5a, the recess 8 extending to the conductive pattern 5. As illustrated in FIG. 1B, within the recess 8, the insulating film 4 remains, in plan view, in a remaining region P including, in the land parts 5a, peripheral edges L2 facing connecting boundaries L1 to the wiring parts 5b. The insulating film 4 is thus left, so that, during bonding of the flexible printed circuit board 2 to the thermally conductive base member 10, even when the peripheral edges L2 of the land parts 5a, facing the connecting boundaries L1 to the wiring parts 5b, are pressed to be bent toward the back-surface side of the flexible printed circuit board 2, the insulating film 4 in the remaining region P can prevent occurrence of short circuits between the land parts 5a and the thermally conductive base member 10. Incidentally, the coverlay 6 is not shown in FIG. 1B.

The recess 8 is formed in a region that overlaps the projection region of the light-emitting diode 3 mounted on the land parts 5a. In other words, the front-side portion of the recess 8 is formed by removing the insulating film 4 in a region, except for the remaining region P, covering the projection region of the light-emitting diode 3. The back-side portion of the recess 8 is formed in a region covering the projection region of the front-side portion. Thus, as described above, the recess 8 has a diameter increased stepwise in the thickness direction such that an opening (back-side portion) in the adhesive layer 7 on the back side is larger and an opening (front-side portion) in the insulating film 4 on the front side is smaller.

Incidentally, in the heat dissipation circuit board 1 in FIG. 1A, the projection region of the plural land parts 5a completely overlaps, in plan view, the opening region (including the remaining region P) of the recess 8 in the insulating film 4. Alternatively, as long as the effect of promoting heat dissipation according to the present invention is exerted, a portion of the projection region of the land parts 5a may not overlap the opening region of the recess 8 in the insulating film 4. The lower limit of the ratio of the overlapped area (except for the remaining region P) between the recess 8 in the insulating film 4 and the land parts 5a to the total area of the land parts 5a is preferably 80%, more preferably 90%, still more preferably 95%. When the area ratio is less than the lower limit, the heat dissipation effect in the heat dissipation circuit board 1 may become insufficient.

The upper limit of the area of the opening of the recess 8 in the insulating film 4 is preferably 2 times the projection area of the light-emitting diode 3, more preferably 1.8 times, still more preferably 1.5 times. When the area of the opening of the recess 8 in the insulating film 4 is more than the upper limit, the removal region of the insulating film 4 becomes large. This may result in insufficient insulation reliability, for example, when the heat dissipation circuit board 1 is placed onto, for example, a bent surface. Incidentally, the phrase “area of the opening of the recess” means the area of the bottom surface of the recess (the exposed back surface of the conductive pattern or the coverlay) and does not include the area of the remaining region P.

The lower limit of the difference between the diameter of the opening of the recess 8 in the insulating film 4 (diameter of the front-side portion) and the diameter of the opening of the recess 8 in the adhesive layer 7 (diameter of the back-side portion) is preferably 2 μm, more preferably 40 μm, still more preferably 100 μm. On the other hand, the upper limit of the difference between the diameter of the opening of the recess 8 in the insulating film 4 and the diameter of the opening of the recess 8 in the adhesive layer 7 is preferably 1000 μm, more preferably 600 μm, still more preferably 200 μM. When the difference between the diameter of the opening of the recess 8 in the insulating film 4 and the diameter of the opening of the recess 8 in the adhesive layer 7 is less than the lower limit, facilitation of the process of filling with the thermally conductive adhesive layers 9a and 9b may become insufficient. Conversely, when the difference between the diameter of the opening of the recess 8 in the insulating film 4 and the diameter of the opening of the recess 8 in the adhesive layer 7 is more than the upper limit, the amount of filling with the thermally conductive adhesive layers 9a and 9b increases, which results in an increase in the cost of the heat dissipation circuit board 1. Incidentally, the phrase “diameter of the opening” means the diameter of a perfect circle having an area equivalent to that of the opening.

The lower limit of a mean overlapped width w between the projection region (remaining region P) of the remaining portion of the insulating film 4 and the projection region of one of the land parts 5a (one of the left and right land parts 5a in FIG. 1A) is preferably 10 μm, more preferably 30 μm, still more preferably 50 μm. On the other hand, the upper limit of the mean overlapped width w is preferably 500 μm, more preferably 300 μm, still more preferably 100 μm. When the mean overlapped width w is less than the lower limit, the effect of preventing short circuits between the land part 5a and the thermally conductive base member 10 may not be sufficiently provided. Conversely, when the mean overlapped width w is more than the upper limit, the heat dissipation effect due to the recess 8 and the thermally conductive adhesive layers 9a and 9b may not be sufficiently provided.

### <Thermally Conductive Adhesive>

The heat dissipation circuit board 1 includes the thermally conductive adhesive layers 9a and 9b. The thermally conductive adhesive layers 9a and 9b are filled into the recess 8 to bond together the conductive pattern 5 and the thermally conductive base member 10. Specifically, the thermally conductive adhesive layer is constituted by the first thermally conductive adhesive layer 9a, which is formed on the conductive pattern 5 and filled into the front-surface side of the recess 8, and the second thermally conductive adhesive layer 9b, which is formed on this first thermally conductive adhesive layer 9a and filled into the back-surface side of the recess 8. In this way, when the thermally conductive adhesive layer is formed so as to be constituted by two different layers, the first layer (first thermally conductive adhesive layer 9a) formed can be examined for the presence or absence of voids before the second layer (second thermally conductive adhesive layer 9b) is formed. Thus, filling with the adhesive can be achieved with certainty to thereby prevent degradation of the thermal conduction property and adhesion strength.

The thermally conductive adhesive layers 9a and 9b contain an adhesive resin component and a thermally conductive filler.

Examples of the adhesive resin component include polyimide, epoxy, alkyd resins, urethane resins, phenolic resins, melamine resins, acrylic resins, polyamide, polyethylene, polystyrene, polypropylene, polyester, vinyl acetate resins, silicone resins, and rubber. When the adhesive resin component is an adhesive containing, as the main component, for example, an acrylic resin, a silicone resin, or a urethane resin, the flexible printed circuit board 2 can be bonded to the thermally conductive base member 10 with ease and certainty.

Examples of the thermally conductive filler include metal oxides and metal nitrides. Examples of the metal oxides include aluminum oxide, silicon oxide, beryllium oxide, and magnesium oxide. Of these, aluminum oxide is preferred from the viewpoint of, for example, the electrical insulation property, thermal conduction property, and price. Examples of the metal nitrides include aluminum nitride, silicon nitride, and boron nitride. Of these, boron nitride is preferred from the viewpoint of the electrical insulation property, thermal conduction property, and low dielectric constant. Incidentally, two or more from the metal oxides and metal nitrides can be used in mixture.

The lower limit of the content of the thermally conductive filler in the thermally conductive adhesive layers 9a and 9b is preferably 40 vol %, more preferably 45 vol %. On the other hand, the upper limit of the content of the thermally conductive filler is preferably 85 vol %, more preferably 80 vol %. When the content of the thermally conductive filler is less than the lower limit, the thermal conduction property of the thermally conductive adhesive layers 9a and 9b may become insufficient. Conversely, when the content of the thermally conductive filler is more than the upper limit, entry of bubbles tends to occur during mixing of the adhesive resin component and the thermally conductive filler, which may result in degradation of dielectric strength. Incidentally, the thermally conductive adhesive layers 9a and 9b may contain, in addition to the thermally conductive filler, another additive such as a curing agent.

The lower limit of the thermal conductivity of the thermally conductive adhesive layers 9a and 9b is preferably 1 W/mK, more preferably 3 W/mK. On the other hand, the upper limit of the thermal conductivity of the thermally conductive adhesive layers 9a and 9b is preferably 20 W/mK. When the thermal conductivity of the thermally conductive adhesive layers 9a and 9b is less than the lower limit, the heat dissipation effect in the heat dissipation circuit board 1 may become insufficient. Conversely, when the thermal conductivity of the thermally conductive adhesive layers 9a and 9b is more than the upper limit, the content of the thermally conductive filler may become excessively high. Thus, entry of bubbles tends to occur during mixing of the adhesive resin component and the thermally conductive filler, which may result in degradation of dielectric strength, or an excessively high cost may be incurred.

The second thermally conductive adhesive layer 9b preferably has a thermal conductivity equal to or lower than the thermal conductivity of the first thermally conductive adhesive layer 9a. In other words, the second thermally conductive adhesive layer 9b preferably has the content of the thermally conductive filler equal to or lower than the content of the thermally conductive filler of the first thermally conductive adhesive layer 9a. The first thermally conductive adhesive layer 9a is thus formed so as to have the content of the thermally conductive filler equal to or higher than the content of the thermally conductive filler of the second thermally conductive adhesive layer 9b, to thereby maintain the heat dissipation effect of the entirety of the thermally conductive adhesive layer and to enhance the adhesion strength to the thermally conductive base member 10.

An adhesive forming the first thermally conductive adhesive layer 9a preferably has thixotropy equal to or higher than the thixotropy of an adhesive forming the second thermally conductive adhesive layer 9b. The adhesive of the first thermally conductive adhesive layer 9a is set to have thixotropy equal to or higher than that of the second thermally conductive adhesive layer 9b, so that the degree of the adhesive filled into the recess 8 is enhanced, which enables formation of the first thermally conductive adhesive layer 9a with more ease and certainty. Incidentally, thixotropy is an index of a property in which viscosity is decreased under the application of a force and the original viscosity is recovered after being left at stand. The thixotropy is represented by, for example, a ratio calculated by dividing a viscosity at a low shear rate by a viscosity at a high shear rate.

The thermally conductive adhesive layers 9a and 9b preferably have a high insulation property. Specifically, the lower limit of the volume resistivity of the thermally conductive adhesive layers 9a and 9b is preferably 1×10⁸ Ωcm, more preferably 1×10¹⁰ Ωcm. When the volume resistivity of the thermally conductive adhesive layers 9a and 9b is less than the lower limit, the thermally conductive adhesive layers 9a and 9b may have a low insulation property, which may result in an electric conduction between the conductive pattern 5 and the thermally conductive base member 10. Incidentally, the volume resistivity is a value measured in accordance with JIS-C2139(2008).

The average thickness of the thermally conductive adhesive layers 9a and 9b as a whole (average distance from the back surface of the second thermally conductive adhesive layer 9b to the back surface of the conductive pattern 5) is preferably larger than the total of the average thickness of the insulating film 4 and the average thickness of the adhesive layer 7. Specifically, the lower limit of the average thickness of the thermally conductive adhesive layers 9a and 9b as a whole is preferably 5 μm, more preferably 10 μm. On the other hand, the upper limit of the average thickness of the thermally conductive adhesive layers 9a and 9b as a whole is preferably 100 μm, more preferably 50 μm. When the thermally conductive adhesive layers 9a and 9b as a whole have an average thickness less than the lower limit, the thermally conductive adhesive layers 9a and 9b may not be in sufficient contact with the thermally conductive base member 10 placed on the back-surface side of the insulating film 4, which may result in insufficient heat dissipation effect. Conversely, when the thermally conductive adhesive layers 9a and 9b as a whole have an average thickness more than the upper limit, the amount of filling with the thermally conductive adhesive layers 9a and 9b as a whole may increase. This may result in an increase in the cost or an excessively large thickness of the heat dissipation circuit board 1.

The lower limit of the ratio of the average thickness of the second thermally conductive adhesive layer 9b to the average thickness of the first thermally conductive adhesive layer 9a is preferably 0.1, more preferably 0.2. On the other hand, the upper limit of the ratio of the average thickness of the second thermally conductive adhesive layer 9b to the average thickness of the first thermally conductive adhesive layer 9a is preferably 2, more preferably 1.5. When the ratio of the average thickness of the second thermally conductive adhesive layer 9b to the average thickness of the first thermally conductive adhesive layer 9a is less than the lower limit, the effect of enhancing adhesion may become insufficient. Conversely, when the ratio of the average thickness of the second thermally conductive adhesive layer 9b to the average thickness of the first thermally conductive adhesive layer 9a is more than the upper limit, the heat dissipation effect may become insufficient.

### <Light-Emitting Diode>

The light-emitting diode 3 is mounted on the plural land parts 5a in the flexible printed circuit board 2. This light-emitting diode 3 may be of the multicolor emission type or the monochrome emission type and may be of the chip type or the surface mount type involving packaging with, for example, a synthetic resin. The light-emitting diode 3 is connected to the land parts 5a via solders 3a. However, the method of connecting the light-emitting diode 3 to the land parts 5a is not limited to soldering, and may be, for example, die bonding using conductive paste or wire bonding using metal wires.

### <Thermally Conductive Base Member>

The thermally conductive base member 10 is a member having a high thermal conductivity. The thermally conductive base member 10 may have the shape of, for example, a plate or a block. Examples of the material for the thermally conductive base member 10 include metals, ceramics, and carbon. Of these, metals are preferably used. Examples of such a metal forming the thermally conductive base member 10 include aluminum, magnesium, copper, iron, nickel, molybdenum, and tungsten. Of these, particularly preferred are aluminum and aluminum alloys that are excellent in terms of the thermal conduction property, workability, and a reduction in weight.

When the thermally conductive base member 10 is formed of a material that is aluminum or an aluminum alloy, the thermally conductive base member preferably has alumite in a surface. The surface of the thermally conductive base member 10 is thus subjected to alumite treatment, so that the durability of the thermally conductive base member 10 can be enhanced, which leads to enhancement of dielectric strength. The alumite preferably has an average thickness of, for example, 10 μm or more and 100 μm or less.

When the thermally conductive base member 10 is formed so as to have the shape of a plate, the lower limit of the average thickness is preferably 0.3 mm, more preferably 0.5 mm. On the other hand, the upper limit of the average thickness of the thermally conductive base member 10 is preferably 5 mm, more preferably 3 mm. When the thermally conductive base member 10 has an average thickness less than the lower limit, the thermally conductive base member 10 may have an insufficient strength. Conversely, when the thermally conductive base member 10 has an average thickness more than the upper limit, it may become difficult to work the thermally conductive base member 10, and the heat dissipation circuit board 1 may have an excessively large weight or volume.

The lower limit of the thermal conductivity of the thermally conductive base member 10 is preferably 50 W/mK, more preferably 100 W/mK. When the thermal conductivity of the thermally conductive base member 10 is less than the lower limit, the heat dissipation effect in the heat dissipation circuit board 1 may become insufficient.

### [Method for Producing Heat Dissipation Circuit Board]

The heat dissipation circuit board 1 can be produced by a production method including a step of forming a laminated body of the insulating film 4, the conductive pattern 5, and the coverlay 6; a step of forming a front-side portion 8a of the recess 8 on a side of the insulating film 4, the side being opposite to a side on which the light-emitting diode 3 is mounted, the recess 8 being in at least a portion of the projection region of the land parts 5a, the recess 8 extending to the conductive pattern 5; a step of mounting the single light-emitting diode 3 on the plural land parts 5a in the laminated body having the front-side portion 8a of the recess 8; a step of forming the adhesive layer 7 on the back surface of the insulating film 4 having the front-side portion 8a of the recess 8, so as to form a back-side portion 8b of the recess 8; a step of filling the recess 8 with the thermally conductive adhesive layers 9a and 9b; and a step of placing the flexible printed circuit board 2 filled with the thermally conductive adhesive layers 9a and 9b, onto a surface of the thermally conductive base member 10.

### (Laminated Body Formation Step)

The laminated body formation step is to form a laminated body illustrated in FIG. 2 and sequentially including, from the back-surface side, the insulating film 4, the conductive pattern 5, and the coverlay 6. Specifically, openings are first formed in the coverlay 6 at positions corresponding to the land parts 5a of the conductive pattern 5 by, for example, punching. Subsequently, a metal foil (or a conductive film) is bonded to the back surface of the coverlay 6, and subjected to, for example, etching to form the conductive pattern 5. The coverlay 6 and the conductive pattern 5 are subsequently placed onto the front surface of the insulating film 4 in which the front-side portion 8a of the recess 8 has been formed by a front-side recess portion formation step described below. Thus, the laminated body is formed.

### (Front-Side Recess Portion Formation Step)

As illustrated in FIG. 2, the front-side recess portion formation step is to remove the insulating film 4, except for the remaining region P, in a region including at least a portion of the projection region of the land parts 5a, to thereby form the front-side portion 8a of the recess 8. When this step is performed before the insulating film 4 is placed onto the coverlay 6 and the conductive pattern 5, the method for removing the insulating film 4 may be punching. Alternatively, when this step is performed after the insulating film 4 is placed onto the coverlay 6 and the conductive pattern 5, examples of the method include a method of immersing, in an etchant, the insulating film 4 masked except for the region to be removed, and a method of irradiating the removal region of the insulating film 4 with a laser.

Incidentally, the laminated body formation step and the front-side recess portion formation step are not necessarily performed in the above-described order, and may be performed in a different order. For example, a metal foil is first placed onto the front surface of the insulating film 4 directly or via an adhesive. Subsequently, the conductive pattern 5 is formed in the metal foil disposed on the front surface of the insulating film 4. The method of placing the metal foil onto the insulating film 4 is not particularly limited. Examples of the method include a bonding method of bonding the metal foil with an adhesive; a casting method of coating the metal foil with a resin composition as a material for an insulating substrate; and a lamination method of bonding the metal foil by heat pressing. The method for forming the conductive pattern 5 is also not particularly limited, and may be a known method such as etching. After the conductive pattern 5 is formed, the coverlay 6 may be placed onto the front surfaces of the insulating film 4 and the conductive pattern 5 to form the laminated body. In this case, openings are formed beforehand in the coverlay 6 at positions corresponding to the land parts 5a of the conductive pattern 5.

### (First Thermally Conductive Adhesive Layer Filling Step)

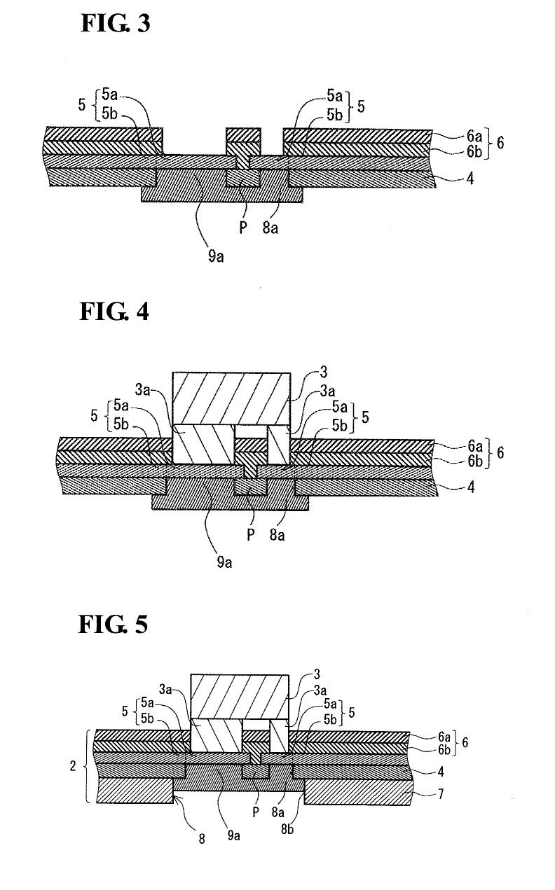

As illustrated in FIG. 3, the first thermally conductive adhesive layer filling step is to fill the recess 8a, which is defined as a portion formed by removing the insulating film 4, with the first thermally conductive adhesive layer 9a. Examples of the method for filling with the first thermally conductive adhesive layer 9a include a method of printing an adhesive for forming the first thermally conductive adhesive layer 9a by screen printing; a method of dispensing, with a dispenser, an adhesive for forming the first thermally conductive adhesive layer 9a; and a method of bonding an adhesive sheet in which an adhesive for forming the first thermally conductive adhesive layer 9a is placed onto a release film. Alternatively, filling with the first thermally conductive adhesive layer may be performed, after an adhesive layer placement step described below, as filling with both of the first thermally conductive adhesive layer and the second thermally conductive adhesive layer.

The lower limit of the viscosity of the first thermally conductive adhesive layer 9a during filling is preferably 10 Pa·s, more preferably 50 Pa·s. On the other hand, the upper limit of the viscosity of the first thermally conductive adhesive layer 9a during filling is preferably 1000 Pa·s, more preferably 500 Pa·s. When the viscosity of the first thermally conductive adhesive layer 9a during filling is less than the lower limit, before the first thermally conductive adhesive layer 9a is cured, the first thermally conductive adhesive layer 9a may flow, which may result in degradation of the degree of filling with the first thermally conductive adhesive layer 9a. Conversely, when the viscosity of the first thermally conductive adhesive layer 9a during filling is more than the upper limit, the first thermally conductive adhesive layer 9a may not be sufficiently filled into the recess 8a.

After filling with the first thermally conductive adhesive layer 9a is performed, the first thermally conductive adhesive layer 9a is cured by heating. The heating temperature at this time may be, for example, 120° C. or more and 200° C. or less. The heating time may be, for example, 30 minutes or more and 600 minutes or less.

### (Light-Emitting Diode Mounting Step)

As illustrated in FIG. 4, the light-emitting diode mounting step is to connect plural terminals of the light-emitting diode 3 to the plural land parts 5a in the laminated body in which the first thermally conductive adhesive layer 9a is formed in the recess 8a, to mount the light-emitting diode 3 on the laminated body. Examples of the method of connecting the light-emitting diode 3 to the land parts 5a include solder reflow, die bonding using conductive paste, and wire bonding using metal wires. Incidentally, FIG. 4 illustrates an example in which the light-emitting diode 3 is mounted with solders 3a.

### (Adhesive Layer Placement Step)

As illustrated in FIG. 5, the adhesive layer placement step is to place, onto the insulating film 4, the adhesive layer 7 in which an opening is formed so as to define the back-side portion 8b of the recess 8 in a region including a region in which the insulating film 4 is removed. This step can be performed by, for example, the following procedure. An adhesive sheet is first prepared that includes a B-stage (semi-cured) adhesive placed by coating on a surface of a first release film, and that includes a second release film placed on the surface of the adhesive. Subsequently, a portion of the adhesive sheet corresponding to the opening region of the adhesive layer 7 is removed for the two release films together by, for example, punching. After that, one of the release films of the adhesive sheet is peeled off and the exposed adhesive surface of the adhesive sheet is placed (temporarily bonded) onto the back surface of the insulating film 4 such that the removed portion (opening portion) of the adhesive sheet overlaps the insulating film 4-removed region (front-side portion 8a of the recess 8). Alternatively, removal for the opening portion may be performed after the adhesive sheet is placed onto the insulating film 4; however, punching cannot be used. Thus, the above-described method is rather performed with higher operability.

### (Second Thermally Conductive Adhesive Layer Filling Step)

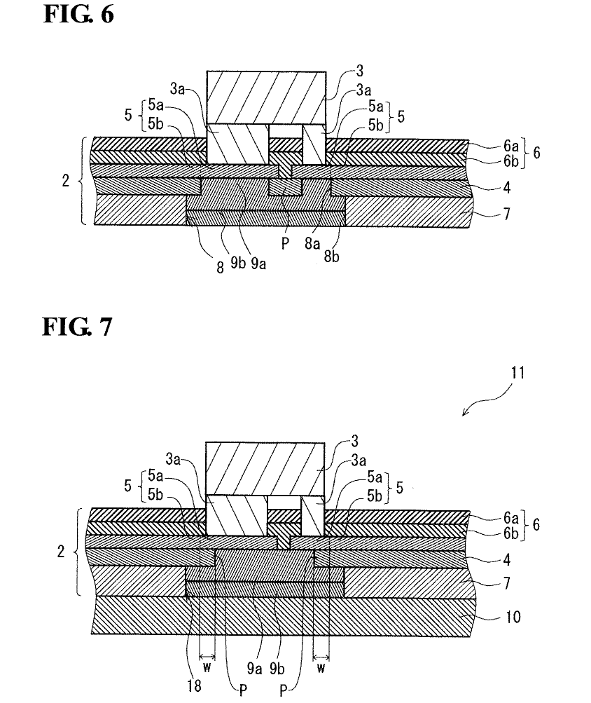

As illustrated in FIG. 6, the second thermally conductive adhesive layer filling step is to perform filling with the second thermally conductive adhesive layer 9b on the back surface of the first thermally conductive adhesive layer 9a in the recess 8, which is defined as the removal portion of the insulating film 4 and the adhesive layer 7. Examples of the method for filling with the second thermally conductive adhesive layer 9b include a method of printing an adhesive for forming the second thermally conductive adhesive layer 9b by screen printing; a method of dispensing, with a dispenser, an adhesive for forming the second thermally conductive adhesive layer 9b; and a method of bonding an adhesive sheet in which an adhesive for forming the second thermally conductive adhesive layer 9b is placed onto a release film. Incidentally, the first thermally conductive adhesive layer filling step may not be performed before the light-emitting diode mounting step and, in this step, filling with both of the first thermally conductive adhesive layer and the second thermally conductive adhesive layer may be performed.

The lower limit of the viscosity of the second thermally conductive adhesive layer 9b during filling is preferably 10 Pa·s, more preferably 50 Pa·s. On the other hand, the upper limit of the viscosity of the second thermally conductive adhesive layer 9b during filling is preferably 1000 Pa·s, more preferably 500 Pa·s. When the viscosity of the second thermally conductive adhesive layer 9b during filling is less than the lower limit, before the second thermally conductive adhesive layer 9b is cured, the second thermally conductive adhesive layer 9b may flow, which may result in degradation of the degree of filling with the second thermally conductive adhesive layer 9b. Conversely, when the viscosity of the second thermally conductive adhesive layer 9b during filling is more than the upper limit, the second thermally conductive adhesive layer 9b may not be sufficiently filled into the recess 8.

### (Thermally Conductive Base Member Placement Step)

The thermally conductive base member placement step is to place the thermally conductive base member 10 onto the back surface of the flexible printed circuit board 2 in which the recess 8 is filled with the thermally conductive adhesive layers 9a and 9b, to thereby obtain the heat dissipation circuit board 1 in FIG. 1A. Specific procedures are as follows. The thermally conductive base member 10 is first placed onto (temporarily bonded to) the back surface of the flexible printed circuit board 2 (the back surfaces of the second thermally conductive adhesive layer 9b and the adhesive layer 7) to obtain a thermally conductive base member laminated body. After that, this thermally conductive base member laminated body is pressed at a relatively low temperature within, for example, a vacuum vessel, to achieve preliminary press-bonding. After the preliminary press-bonding, the thermally conductive base member laminated body is heated at a high temperature to cure the thermally conductive adhesive layers 9a and 9b and the adhesive layer 7. Thus, the heat dissipation circuit board 1 is obtained.

The pressure to the thermally conductive base member laminated body during the preliminary press-bonding may be, for example, 0.05 MPa or more and 1 MPa or less. The temperature during the preliminary press-bonding is preferably, for example, 70° C. or more and 120° C. or less.

The temperature during the high-temperature heating of the thermally conductive base member laminated body may be, for example, 120° C. or more and 200° C. or less. The time for the high-temperature heating may be, for example, 30 minutes or more and 600 minutes or less.

### <Advantages>

The heat dissipation circuit board 1 includes the recess 8 in at least a portion of the projection region of the land parts 5a for the light-emitting diode 3, the recess 8 extending to the conductive pattern 5; and the recess 8 is filled with a thermally conductive adhesive. Thus, the thermally conductive adhesive layers 9a and 9b are directly disposed on the conductive pattern 5 of the printed circuit board 2. Accordingly, in the heat dissipation circuit board 1, the conductive pattern 5 is connected to the thermally conductive base member 10 via the thermally conductive adhesive, to thereby considerably promote the heat dissipation effect for the light-emitting diode 3. In the heat dissipation circuit board 1, the insulating film 4 is left in a region including, in the land parts 5a, at least a portion of the peripheral edges facing the connecting boundaries to the wiring parts 5b, to thereby prevent occurrence of short circuits caused by contacting of the conductive pattern 5 with the thermally conductive base member 10.

In the heat dissipation circuit board 1, the recess 8 is formed in a region overlapping the projection region of the light-emitting diode 3, which is mounted on the land parts 5a positioned at the bottom surface of the recess 8. Thus, the heat conducted through the thermally conductive adhesive layers 9a and 9b passes in the thickness direction of the land parts 5a of the conductive pattern 5 to reach the thermally conductive base member 10. Accordingly, in the heat dissipation circuit board 1, the heat dissipation effect for the light-emitting diode 3 can be further enhanced.

Furthermore, in the heat dissipation circuit board 1, the recess 8 has a diameter increased stepwise so as to have a larger opening in the adhesive layer 7 on the back side, and a smaller opening in the insulating film 4 on the front side. This facilitates the process of achieving alignment between the insulating film 4 and the adhesive layer 7 in the adhesive layer placement step, and also facilitates the process of filling the recess 8 with the thermally conductive adhesive layers 9a and 9b in the thermally conductive adhesive layer filling step.

Since the heat dissipation circuit board 1 includes the flexible printed circuit board 2 having flexibility, it can be easily disposed so as to conform to a thermally conductive base member having, for example, a curved surface.

### Second Embodiment

A heat dissipation circuit board 11 illustrated in FIG. 7 mainly includes a flexible printed circuit board 2 having flexibility, a light-emitting diode 3 mounted on this flexible printed circuit board 2, and a thermally conductive base member 10 disposed on the back-surface side of the flexible printed circuit board 2. This flexible printed circuit board 2 includes a recess 18 on a side opposite to a side on which the light-emitting diode 3 is mounted, the recess 18 being in at least a portion of the projection region of land parts 5a, the recess 18 extending to a conductive pattern 5. This recess 18 is filled with thermally conductive adhesive layers 9a and 9b. The flexible printed circuit board 2 in the heat dissipation circuit board 11 in FIG. 7 is the same as the flexible printed circuit board 2 in the heat dissipation circuit board 1 in FIG. 1 except for the recess 18. The light-emitting diode 3 and the thermally conductive base member 10 are the same as in the heat dissipation circuit board 1 in FIG. 1. Accordingly, the same reference signs are used and redundant descriptions will be omitted.

### (Recess)

The heat dissipation circuit board 11 includes the recess 18 on a side of the flexible printed circuit board 2, the side being opposite to a side on which the light-emitting diode 3 is mounted, the recess 18 being in at least a portion of the projection region of the land parts 5a, the recess 18 extending to the conductive pattern 5. Within the recess 18, the insulating film 4 remains, in plan view, in remaining regions P including, in the land parts 5a, connecting boundaries to the wiring parts 5b. The insulating film 4 is thus left, so that, when the flexible printed circuit board 2 is bonded to the thermally conductive base member 10, the amount of the conductive pattern 5 pressed toward the back-surface side of the flexible printed circuit board 2 is decreased. As a result, short circuits between the land parts 5a and the thermally conductive base member 10 can be prevented.

As with the recess 8 of the heat dissipation circuit board 1 of the first embodiment above, the recess 18 is formed in a region overlapping the projection region of the light-emitting diode 3, which is mounted on the land parts 5a disposed at the bottom surface of the recess 18. In other words, the front-side portion of the recess 18 is formed by removing, except for the remaining regions P, the insulating film 4 that is in a region covering the projection region of the light-emitting diode 3. The back-side portion of the recess 18 is formed in a region covering the projection region of the front-side portion. The ratio of the overlapped area between the recess 18 and the land parts 5a in the insulating film 4 to the total area of the land parts 5a, the area of an opening of the recess 18 in the insulating film 4, and the difference between the diameter of an opening of the recess 18 in the insulating film 4 (diameter of the front-side portion) and the diameter of an opening of the recess 18 in the adhesive layer 7 (diameter of the back-side portion) can be set to the same as in the recess 8 of the heat dissipation circuit board 1 of the first embodiment above.

The lower limit of the mean overlapped width w between the projection region (remaining region P) of a remaining portion of the insulating film 4 and the projection region of one of the land parts 5a (one of the left and right land parts 5a in FIG. 7), with respect to the average length of the land part 5a in the connection direction of the land part 5a to the wiring part 5b, is preferably 1%, more preferably 5%, still more preferably 10%. On the other hand, the upper limit of the mean overlapped width w, with respect to the average length of the land part 5a in the connection direction of the land part 5a to the wiring part 5b, is preferably 20%, more preferably 15%, still more preferably 12%. When the mean overlapped width w is less than the lower limit, the effect of preventing short circuits between the land parts 5a and the thermally conductive base member 10 may become insufficient. Conversely, when the mean overlapped width w is more than the upper limit, the heat dissipation effect due to the recess 18 and the thermally conductive adhesive layers 9a and 9b may become insufficient. Incidentally, the phrase “the connection direction of the land part to the wiring part” means a direction along a straight line that passes the center of the connecting boundary, to the wiring part, of the land part, the connecting boundary overlapping the remaining region P, and that passes the geometric center of gravity of the land part.

### Third Embodiment

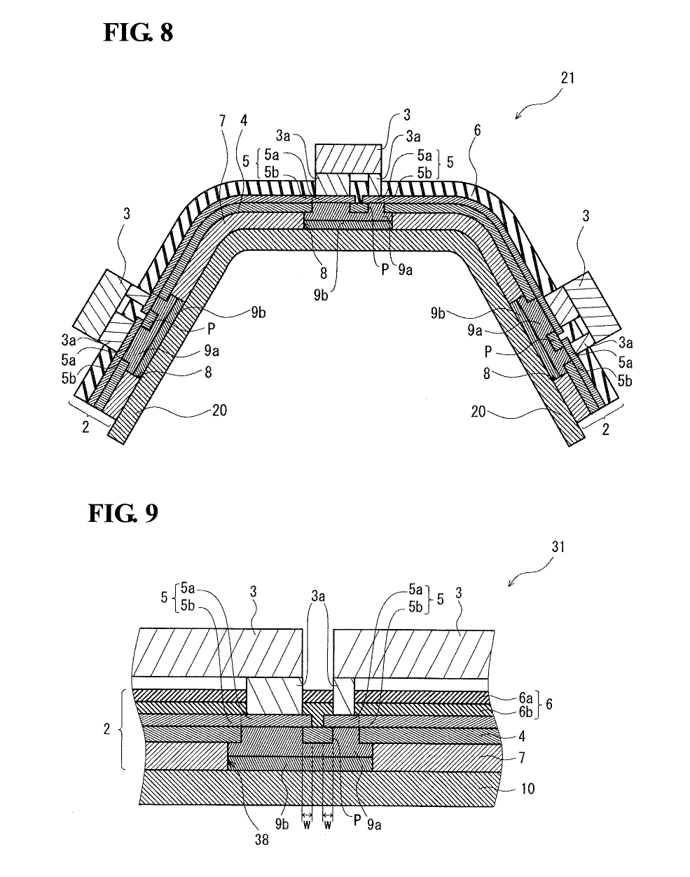

A heat dissipation circuit board 21 illustrated in FIG. 8 mainly includes a flexible printed circuit board 2 having flexibility, plural light-emitting diodes 3 mounted on the flexible printed circuit board 2, and a thermally conductive base member 20 disposed on the back-surface side of the flexible printed circuit board 2. The flexible printed circuit board 2 includes recesses 8 on a side opposite to a side on which the light-emitting diodes 3 are mounted, the recesses 8 being in at least portions of the projection regions of land parts 5a, the recesses 8 extending to a conductive pattern 5. These recesses 8 are filled with thermally conductive adhesive layers 9a and 9b. The flexible printed circuit board 2 and the light-emitting diodes 3 in the heat dissipation circuit board 21 in FIG. 8 are the same as in the heat dissipation circuit board 1 in FIG. 1. Accordingly, the same reference signs are used and redundant descriptions will be omitted.

### <Thermally Conductive Base Member>

The thermally conductive base member 20 is a plate-shaped metal member, and includes a curved surface or a bent surface in a region on which the flexible printed circuit board 2 is disposed. Specifically, the thermally conductive base member 20 is curved or bent so as to have a convex surface on which the flexible printed circuit board 2 is disposed. Thus, the flexible printed circuit board 2 is curved or bent along the surface of the thermally conductive base member 20. The thermally conductive base member 20 is thus curved or bent, so that the plural light-emitting diodes 3 mounted on the flexible printed circuit board 2 can be disposed so as to have different emission directions. For example, an LED lighting apparatus including the heat dissipation circuit board 21 enables reduction in variations in luminous intensity depending on relative positions.

The material and average thickness of the thermally conductive base member 20 can be set as in the thermally conductive base member 10 of the heat dissipation circuit board 1 of the first embodiment above.

Incidentally, the light-emitting diodes 3 are preferably mounted at positions other than the curved surfaces and the bent surfaces of the thermally conductive base member 20 and the flexible printed circuit board 2 from the viewpoint of connection reliability. FIG. 8 illustrates three light-emitting diodes 3. However, the number of the light-emitting diodes 3 mounted on the heat dissipation circuit board 21 is not limited to three, and may be two or four or more.

### Fourth Embodiment

A heat dissipation circuit board 31 illustrated in FIG. 9 mainly includes a flexible printed circuit board 2 having flexibility, plural light-emitting diodes 3 mounted on the flexible printed circuit board 2, and a thermally conductive base member 10 disposed on the back-surface side of the flexible printed circuit board 2. The flexible printed circuit board 2 includes a recess 38 on a side opposite to a side on which the light-emitting diodes 3 are mounted, the recess 38 being in at least a portion of the projection regions of land parts 5a, the recess 38 extending to a conductive pattern 5. The recess 38 is filled with thermally conductive adhesive layers 9a and 9b. The flexible printed circuit board 2 in the heat dissipation circuit board 31 in FIG. 9 is the same as the flexible printed circuit board 2 in the heat dissipation circuit board 1 in FIG. 1 except for the recess 38. The light-emitting diodes 3 and the thermally conductive base member 10 are the same as in the heat dissipation circuit board 1 in FIG. 1. Accordingly, the same reference signs are used and redundant descriptions will be omitted.

### (Recess)

In the heat dissipation circuit board 31, the recess 38 is formed so as to include the projection region of a single land part 5a to which a single terminal of a single light-emitting diode 3 is connected and so as to include the projection region of a single land part 5a to which a single terminal of another light-emitting diode 3 is connected, in other words, so as to extend over the plural light-emitting diodes 3. Within the recess 38, the insulating film 4 remains, in plan view, in a remaining region P including, in the land parts 5a, plural peripheral edges facing the connecting boundaries to the wiring parts 5b. As a result, the heat dissipation circuit board 31 enables enhancement of the heat dissipation effect for the plural light-emitting diodes 3, and prevention of occurrence of short circuits caused by contacting of the conductive pattern 5 with the thermally conductive base member 10.

### Other Embodiments

The embodiments disclosed herein should be understood as examples in all respects and not being restrictive. The scope of the present invention is not limited to the configurations of the above-described embodiments but is indicated by Claims. The scope of the present invention is intended to embrace all the modifications within the meaning and range of equivalency of the Claims.

The heat dissipation circuit board may be provided so as to include a release film disposed on the back surfaces of the thermally conductive adhesive layer and the adhesive layer, that is, without including the thermally conductive base member. This release film may be a resin film having a surface treated so as to be releasable. This release film is peeled off when the heat dissipation circuit board is bonded to a thermally conductive base member such as a metal plate.

In the first embodiment and the second embodiment above, a single light-emitting diode is mounted. Alternatively, two or more light-emitting diodes may be mounted.

In the above-described embodiments, light-emitting diodes are mounted on printed circuit boards. However, an electronic component other than light-emitting diodes may be mounted on such a printed circuit board. A single electronic component is not necessarily mounted on plural land parts, and may be mounted on a single land part.

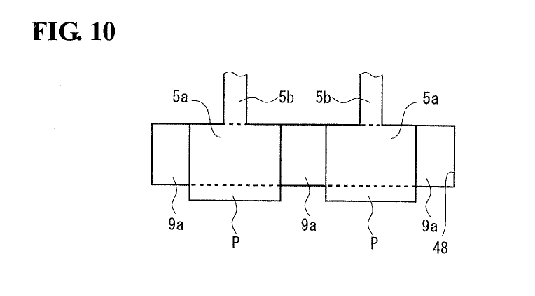

As illustrated in FIG. 10, the present invention is also applicable to a printed circuit board having a conductive pattern in which plural land parts 5a are disposed such that connecting boundaries to wiring parts 5b do not face each other. In the case of such a conductive pattern, advantages of the present invention can be provided by forming a recess 48 in a region including the projection regions of the land parts 5a, and by forming a remaining region P of the insulating film for each land part 5a, in the connecting boundary to the wiring part 5b or in the peripheral edge facing the connecting boundary. Incidentally, FIG. 10 illustrates a case where, in each land part 5a, a remaining region P is provided in the peripheral edge facing the connecting boundary to the wiring part 5b.

When plural wiring parts are connected to a single land part, that is, a single land part has connecting boundaries to plural wiring parts, the insulating film is left, in plan view, at least in a region including a single connecting boundary or a peripheral edge facing a single connecting boundary. However, in order to provide the effect of preventing short circuits with certainty, the insulating film is preferably left, in plan view, in regions including all the connecting boundaries or peripheral edges facing all the connecting boundaries.

The insulating film may be left, in plan view, in a single land part, in both of a region including a connecting boundary to a wiring part and a region including a peripheral edge facing the connecting boundary.

In each of the above-described embodiments, the recess is formed in a region including the projection regions of plural land parts. Alternatively, the recess may be formed so as to include the projection region of a single land part. In addition, the region where the recess is formed may include a region not overlapping the projection regions of electronic components and land parts.

In the heat dissipation circuit board, the recess may have the same diameter for the opening in the insulating film (front-surface side) and the opening in the adhesive layer (back-surface side). In other words, the recess may have a constant opening area in the thickness direction of the printed circuit board.

The thermally conductive adhesive layer does not necessarily have a bilayer configuration and may have a monolayer configuration. When the thermally conductive adhesive layer has a bilayer configuration, a thermally conductive adhesive of the same type may be used to form the bilayer configuration. Specifically, a thermally conductive adhesive is filled into a recess and heat-cured to form the first thermally conductive adhesive layer, and the same thermally conductive adhesive is subsequently filled in over the back surface of the first thermally conductive adhesive layer to form the second thermally conductive adhesive layer. Thus, a thermally conductive adhesive layer having a bilayer configuration can be obtained. Incidentally, three or more thermally conductive adhesives may be used.

A printed circuit board used in the present invention is not limited to a flexible printed circuit board having flexibility, and may be a rigid printed circuit board. A printed circuit board used in the present invention is not limited to those used in the above-described embodiments as long as it includes a land part in the front surface and includes an insulating film (base film) on the back surface. Examples of the printed circuit board include a double-sided printed circuit board having a conductive pattern on both surfaces of an insulating film; and a multilayer printed circuit board in which plural insulating films with conductive patterns are stacked. In the case of such a double-sided printed circuit board or a multilayer printed circuit board, the heat dissipation effect can be promoted by making a thermally conductive adhesive be in contact with the conductive pattern disposed on the most back-surface side (opposite to a surface on which an electronic component is mounted).

### EXAMPLES

Hereinafter, the present invention will be described more specifically with reference to Examples. However, the present invention is not limited to the following Examples.

[No. 1]

A laminated body is first prepared in which a base film (insulating film) containing polyimide as the main component and having an average thickness of 25 μm, a conductive pattern formed from a copper foil and having an average thickness of 35 μm, and a coverlay that includes an insulating layer containing polyimide as the main component and having an average thickness of 25 μm and that includes an adhesion layer having an average thickness of 30 μm are stacked from the back-surface side in this order. Incidentally, this laminated body has, in the front surface (front surface of the coverlay), a white coating having a reflectivity of 85% for a wavelength of 550 nm. This laminated body includes, in the conductive pattern, a pair of land parts on which an LED (light-emitting diode) is mountable; openings are formed in the coverlay so as to correspond to the land parts. Incidentally, the pair of land parts is rectangular, and the distance between the peripheral edges facing each other is 100 μm.

Subsequently, in the projection region (having an area equal to the area of the land parts) of a region on which an LED is to be mounted in the laminated body, the base film is removed with an etchant to form a recess to expose the conductive pattern. At this time, the base film is left in a region including, in two land parts on which the LED is mounted, peripheral edges facing connecting boundaries to wiring parts. The mean overlapped width between the projection region of the remaining portion of the base film and the projection region of a single land part is set to 230 μm. That is, the mean width of the remaining portion in the direction in which the land parts forming a pair are arranged in parallel is 560 μm. After that, the land parts are subjected to screen printing with lead-free solder (Sn-3.0Ag-0.5Cu) through a metal mask having an average thickness of 150 μM. On this solder a white LED (NS2W757DR from Nichia Corporation) is placed. The solder is subjected to reflowing to mount the LED.

Subsequently, in a polyethylene terephthalate film (release film) having a surface treated to be releasable, the surface is coated with an epoxy-based adhesive. The adhesive is dried so as to be in the B stage and have an average thickness of 20 μm. On the surface of the adhesive, a release film is placed to form an adhesive sheet. This adhesive sheet is cut out for a portion corresponding to the projection region of an LED mount region (the portion having an area equal to the area of the land parts), and the adhesive sheet is simultaneously punched out so as to correspond to the outer shape of the laminated body. After that, one of the release films of the adhesive sheet is peeled off. The adhesive sheet is temporarily bonded to the back surface of the laminated body such that the cut-out portion matches the conductive-pattern-exposed region of the base film. Thus, a flexible printed circuit board is obtained.

After the adhesive sheet is temporarily bonded (after the adhesive layer is placed), the cut-out portion (the portion formed by removing the base film and the adhesive) of the flexible printed circuit board is filled with, by screen printing, a thermally conductive adhesive that has a thermal conductivity of 2.2 W/mK and is prepared by mixing an epoxy-based adhesive, a curing agent, alumina particles having a particle size of 5 to 30 μm, and alumina particles having a particle size of 0.1 to 1 μm.

After filling with the thermally conductive adhesive, the release film on the back surface of the adhesive sheet is peeled off, and the adhesive sheet is temporarily bonded to an aluminum plate having an average thickness of 1 mm. This laminated body is heated in a vacuum vessel at 100° C. to decrease the viscosity of the adhesive. Subsequently, the flexible printed circuit board on which the LED is mounted with silicone rubber is pressed, from the front-surface side, with a pressure of 0.1 MPa to perform preliminary press-bonding. Thus, an aluminum-plate laminated body is produced. After that, the aluminum-plate laminated body is taken out of the vacuum vessel, placed into a preheated oven, and heated at 150° C. for 120 minutes to cure the adhesives. Thus, a circuit board No. 1 is obtained.

[No. 2]

A circuit board No. 2 is obtained as in No. 1 except that removal of the base film, cutting out of the adhesive sheet, and filling with the thermally conductive adhesive are not performed.

### Reference Example 1

Instead of the base film containing polyimide as the main component and the aluminum plate, an aluminum substrate having an average thickness of 1 mm is used. On this aluminum substrate, a conductive pattern as in No. 1 is formed with an adhesive layer having an average thickness of 80 μm therebetween and an LED is mounted. Thus, a circuit board of Reference Example 1 is obtained.

### Reference Example 2

A circuit board of Reference Example 2 is obtained as in No. 1 except that, during removal of the base film, the base film is not left, in plan view, in the region including, in land parts, peripheral edges facing connecting boundaries to wiring parts.

[Evaluation]

The circuit boards of Nos. 1 and 2 and Reference Examples 1 and 2 above were subjected to thermal analysis by the finite element method in which the air surrounding the circuit boards had a thermal transfer coefficient of 5 W/m²K. On the basis of the thermal analysis results, the difference between the minimum temperature of the aluminum plate or aluminum substrate and the temperature of the LED was evaluated as an increase in the temperature.

TABLE 1

| | Increase in the temperature |
|---|---|
| | ° C. |
| No. 1 | 5.7 |
| No. 2 | 8.2 |
| Reference Example 1 | 5.6 |
| Reference Example 2 | 5.5 |

As described in Table 1, the circuit board No. 1 provides a stronger heat dissipation effect than No. 2 in which the base film is not removed, and provides a heat dissipation effect equivalent to that of the circuit board of Reference Example 1 using the aluminum substrate, and that of the circuit board of Reference Example 2 in which the base film is not left in the region including, in land parts, peripheral edges facing connecting boundaries to wiring parts.

### INDUSTRIAL APPLICABILITY

As has been described, a heat dissipation circuit board and a method for producing the heat dissipation circuit board according to the present invention can provide a circuit board that has high insulation reliability, can effectively promote heat dissipation from a mounted electronic component, and is suitably applicable to, for example, LED lighting apparatuses.

### REFERENCE SIGNS LIST

1, 11, 21, and 31 heat dissipation circuit boards
2 flexible printed circuit board
3 light-emitting diode
3a solder
4 insulating film
5 conductive pattern
5a land part
5b wiring part
6 coverlay
6a insulating layer
6b adhesion layer
7 adhesive layer
8, 18, 38, and 48 recesses
8a front-side portion
8b back-side portion
9a first thermally conductive adhesive layer
9b second thermally conductive adhesive layer
10 and 20 thermally conductive base members
P remaining region
L1 connecting boundary
L2 peripheral edge

1. A heat dissipation circuit board comprising:
a printed circuit board including an insulating film and a conductive pattern that is formed on a front-surface side of the insulating film and includes at least one land part and a wiring part connected to the at least one land part; and
at least one electronic component mounted on a front-surface side of the at least one land part,
wherein the printed circuit board includes a recess on a side opposite to a side on which the at least one electronic component is mounted, the recess being in at least a portion of a projection region of the at least one land part, the recess extending to the conductive pattern, and
includes a thermally conductive adhesive layer filling the recess, and
the insulating film remains, in plan view, in a region including, in the at least one land part, at least a portion of a connecting boundary to the wiring part or at least a portion of a peripheral edge facing the connecting boundary.

2. The heat dissipation circuit board according to claim 1, wherein the insulating film is present, in plan view, in a region including, in the at least one land part, the peripheral edge facing the connecting boundary to the wiring part.

3. The heat dissipation circuit board according to claim 2, wherein a mean overlapped width between a projection region of a remaining portion of the insulating film and a projection region of one of the at least one land part is 10 μm or more and 500 μm or less.

4. The heat dissipation circuit board according to claim 1, wherein the insulating film is present, in plan view, in a region including, in the at least one land part, the connecting boundary to the wiring part.

5. The heat dissipation circuit board according to claim 1, wherein the thermally conductive adhesive layer includes a first thermally conductive adhesive layer formed on the conductive pattern, and a second thermally conductive adhesive layer formed on the first thermally conductive adhesive layer, the second thermally conductive adhesive layer having a thermal conductivity equal to or lower than a thermal conductivity of the first thermally conductive adhesive layer.

6. The heat dissipation circuit board according to claim 1, wherein the recess has a diameter increased stepwise so as to have a larger opening on a back side and a smaller opening on a front side.

7. The heat dissipation circuit board according to claim 1, wherein the printed circuit board has flexibility.

8. The heat dissipation circuit board according to claim 1, further comprising a thermally conductive base member on a surface of the thermally conductive adhesive layer, the surface being on a side opposite to the conductive pattern.

9. The heat dissipation circuit board according to claim 8, wherein the thermally conductive base member is formed of aluminum or an aluminum alloy.

10. The heat dissipation circuit board according to claim 9, wherein the thermally conductive base member contains alumite in a surface that is disposed on the thermally conductive adhesive layer.

11. A method for producing a heat dissipation circuit board including a printed circuit board including an insulating film and a conductive pattern that is formed on a front-surface side of the insulating film and includes at least one land part and a wiring part connected to the at least one land part, and at least one electronic component mounted on a front-surface side of the at least one land part, the method comprising:
a step of mounting the at least one electronic component on the at least one land part;
a step of forming a recess on a side of the printed circuit board, the side being opposite to a side on which the at least one electronic component is mounted, the recess being in at least a portion of a projection region of the at least one land part, the recess extending to the conductive pattern; and
a step of filling the recess with a thermally conductive adhesive,
wherein in the step of forming the recess, the insulating film is removed except for, in plan view, a region including, in the at least one land part, at least a portion of a connecting boundary to the wiring part or at least a portion of a peripheral edge facing the connecting boundary.
